(19) United States
(12) Patent Application Publication
(10) Pub. No.: US 2009/0268190 A1
(43) Pub. Date: Oct. 29, 2009

(54) LITHOGRAPHIC APPARATUS AND DEVICE MANUFACTURING METHOD

(75) Inventors: Jacobus Frederik Molenaar, Utrecht (NL); Michael Johannes Vervoordeldonk, Rosmalen (NL); Funda Sahin Nomaler, Eindhoven (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 12/428,110

(22) Filed: Apr. 22, 2009

Related U.S. Application Data
(60) Provisional application No. 61/071,346, filed on Apr. 23, 2008.

(51) Int. Cl. G03B 27/58; G03F 7/20

(52) U.S. Cl. 355/72; 430/325

(57) ABSTRACT

A lithographic apparatus includes a bearing configured to support a first part with respect to a second part of the apparatus in a first direction such that the first part is moveable in a second direction relative to the second part. The bearing passively supports the first part in three degrees of freedom. The first part is coupled to at least one permanent magnet, and the second part is coupled to at least two permanent magnets. The permanent magnet of the first part is positioned substantially between the permanent magnets of the second part. A field orientation of the permanent magnets is substantially parallel to the first direction and the permanent magnet of the first part has a substantially opposite polarity to at least one of the magnets of the second part.

### CROSS-REFERENCE TO RELATED APPLICATIONS

This application claims the benefit of priority from U.S. Provisional Patent Application No. 61/071,346, filed on Apr. 23, 2008, the entire content of which is incorporated herein by reference.

### FIELD

The present invention relates to a lithographic apparatus that includes a bearing configured to support a first part of the lithographic apparatus with respect to a second part of the lithographic apparatus such that the first part is moveable with respect to the second part.

### BACKGROUND

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

United States Patent Application Publication No. 2005/0168086 discloses a magnetic floating device provided with a bearing configured to support a first part of the lithographic apparatus with respect to a second part, such that the first part is moveable with respect to the second part, and the first part being provided with at least one permanent magnet and the second part being provided with at least two permanent magnets which are positioned aside the at least one permanent magnet of the first part.

### SUMMARY

It is desirable to provide an improved bearing.

According to an embodiment of the invention, there is provided a lithographic apparatus that includes an illumination system configured to provide a radiation beam and a support configured to support a patterning device. The patterning device is configured to impart the radiation beam with a pattern in its cross-section to form a patterned radiation beam. The apparatus further includes a substrate table configured to hold a substrate, a projection system configured to project the patterned radiation beam onto a target portion of the substrate, and a bearing configured to support a first part of the lithographic apparatus with respect to a second part of the lithographic apparatus in a first direction such that the first part is moveable in a second direction relative to the second part. The second direction is substantially perpendicular to the first direction. The first part is coupled to at least one permanent magnet and the second part is coupled to at least two permanent magnets. The permanent magnet of the first part is positioned substantially between the permanent magnets of the second part. A field orientation of the permanent magnets is substantially parallel to the first direction and the at least one permanent magnet of the first part has a substantially opposite polarity to at least one of the magnets of the second part. The bearing restricts rotational movement of the first part around the second direction and it restricts rotational movement of the first part around a third direction. The third direction is substantially perpendicular to the first direction and the second direction.

According to an embodiment of the invention, there is provided a device manufacturing method that includes providing a substrate that is at least partially covered by a layer of radiation-sensitive material on a substrate table, providing a patterning device on a support, projecting a patterned beam of radiation onto the layer of radiation sensitive material, and supporting with a bearing a first part of the lithographic apparatus with respect to a second part of the lithographic apparatus in a first direction such that the first part is moveable in a second direction relative to the second part. The second direction is substantially perpendicular to the first direction. The first part is coupled to at least one permanent magnet, and the second part is coupled to at least two permanent magnets. The permanent magnet of the first part is positioned substantially between the permanent magnets of the second part and a field orientation of the permanent magnets is substantially parallel to the first direction. The at least one permanent magnet of the first part has a substantially opposite polarity to at least one of the magnets of the second part. The method further includes restricting rotational movement of the first part around the second direction, restricting rotational movement of the first part around a third direction, wherein the third direction is substantially perpendicular to the first direction and the second direction, moving the first part with respect to the second part, developing the layer of sensitive material on the substrate, and manufacturing a device from the developed substrate.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 schematically depicts a bearing for use in a lithographic apparatus according to an embodiment of the invention;

FIG. 3 depicts a view in three dimensions of the bearing of FIG. 2;

FIG. 4 depicts a support for supporting a patterning device or a reticle masking device in a lithographic apparatus according to the invention;

FIG. 5 depicts the support of FIG. 4 according to an embodiment of the invention that includes actuators and sensors;

FIGS. 6A and B depict configurations of permanent magnets according to further embodiments of the invention;

FIGS. 7A, B and C depict configurations of permanent magnets according to further embodiments of the invention; and

FIGS. 8A and B depict configurations of permanent magnets according to a further embodiment of the invention.

### DETAILED DESCRIPTION

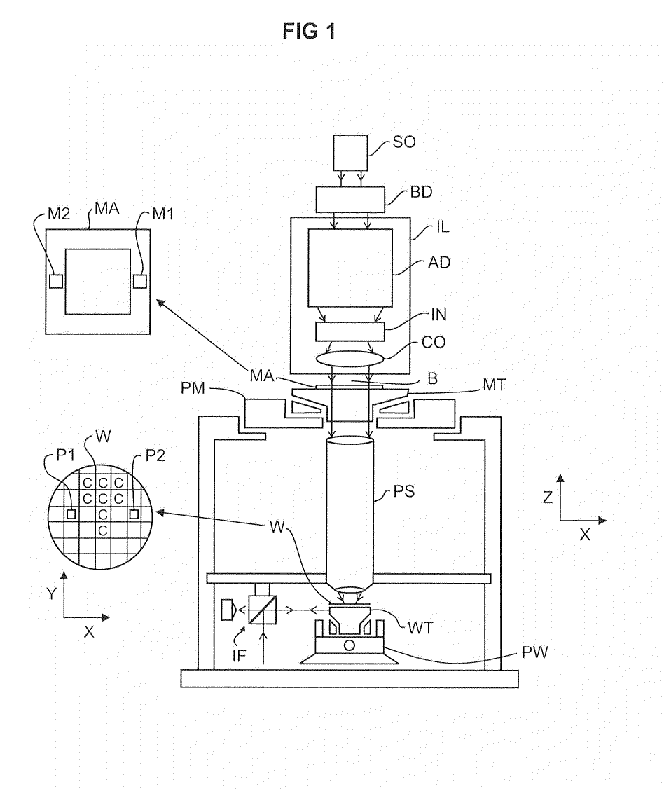

FIG. 1 schematically depicts a lithographic apparatus according to one embodiment of the invention. The apparatus includes an illumination system (illuminator) IL configured to condition a radiation beam B (e.g. UV radiation or any other suitable radiation), a mask support structure (e.g. a mask table) MT constructed to support a patterning device (e.g. a mask) MA and connected to a first positioning device PM configured to accurately position the patterning device in accordance with certain parameters. The apparatus also includes a substrate table (e.g. a wafer table) WT or “substrate support” constructed to hold a substrate (e.g. a resist-coated wafer) W and connected to a second positioning device PW configured to accurately position the substrate in accordance with certain parameters. The apparatus further includes a projection system (e.g. a refractive projection lens system) PS configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, for directing, shaping, or controlling radiation.

The mask support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. The mask support structure can use mechanical, vacuum, electrostatic or other clamping techniques to hold the patterning device. The mask support structure may be a frame or a table, for example, which may be fixed or movable as required. The mask support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section so as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables or “substrate supports” (and/or two or more mask tables or “mask supports”). In such “multiple stage” machines the additional tables or supports may be used in parallel, or preparatory steps may be carried out on one or more tables or supports while one or more other tables or supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques can be used to increase the numerical aperture of projection systems. The term “immersion” as used herein does not mean that a structure, such as a substrate, must be submerged in liquid, but rather only means that a liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the mask support structure (e.g., mask table MT), and is patterned by the patterning device. Having traversed the mask MA, the radiation beam B passes through the projection system PS, which focuses the beam onto a target portion C of the substrate W. With the aid of the second positioning device PW and position sensor IF (e.g. an interferometric device, linear encoder or capacitive sensor), the substrate table WT can be moved accurately, e.g. so as to position different target portions C in the path of the radiation beam B. Similarly, the first positioning device PM and another position sensor (which is not explicitly depicted in FIG. 1) can be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioning device PM. Similarly, movement of the substrate table WT or “substrate support” may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT or “mask support” and the substrate table WT or “substrate support” are kept essentially stationary, while an entire pattern imparted to the radiation beam is projected onto a target portion C at one time (i.e. a single static exposure). The substrate table WT or “substrate support” is then shifted in the X and/or Y direction so that a different target portion C can be exposed. In step mode, the maximum size of the exposure field limits the size of the target portion C imaged in a single static exposure.

2. In scan mode, the mask table MT or “mask support” and the substrate table WT or “substrate support” are scanned synchronously while a pattern imparted to the radiation beam is projected onto a target portion C (i.e. a single dynamic exposure). The velocity and direction of the substrate table WT or “substrate support” relative to the mask table MT or “mask support” may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT or “mask support” is kept essentially stationary holding a programmable patterning device, and the substrate table WT or “substrate support” is moved or scanned while a pattern imparted to the radiation beam is projected onto a target portion C. In this mode, generally a pulsed radiation source is employed and the programmable patterning device is updated as required after each movement of the substrate table WT or “substrate support” or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

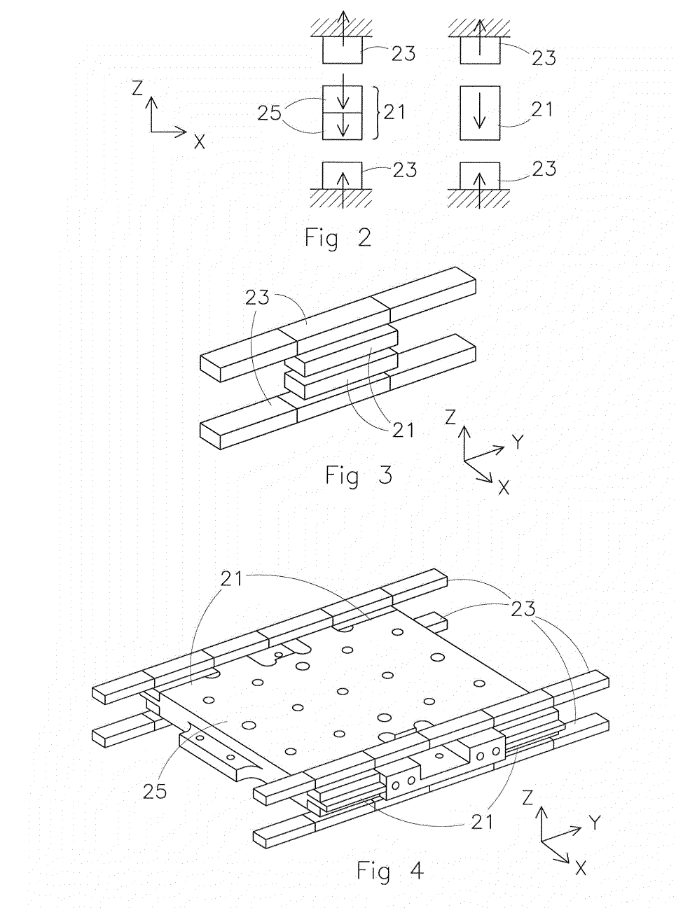

FIG. 2 schematically depicts a bearing for use in a lithographic apparatus according to an embodiment of the present invention. The bearing supports a first part of the lithographic apparatus with respect to a second part of the lithographic apparatus in the Z-direction such that the first part is moveable in the Y-direction relative to the second part. Permanent magnet 21 is coupled to a moveable first part of the lithographic apparatus and permanent magnets 23 are coupled to a non moveable second part of the lithographic apparatus. The field orientation of the permanent magnets 21 and 23 is indicated by the arrows in the magnets and is substantially parallel to the Z-direction. Permanent magnet 21 has a substantially opposite polarity to the permanent magnets 23. Magnetic forces between magnet 21 and magnets 23 create a repulsive force which forms a bearing with an improved stiffness. Permanent magnet 21 may also comprise two or more permanent magnets 25 which would act as a single large permanent magnet. The permanent magnet 21 may also have a slight offset in the X-direction which makes the first moveable part also moveable over a short range in the X-direction, while decreasing the stiffness in the Z-direction only by a small amount. The X, Y and Z-direction are orthogonal with respect to each other. The bearing restricts rotational movements Ry (around the Y-direction) and Rx (around the X-direction).

FIG. 3 depicts a view in three dimensions of the bearing of FIG. 2. Permanent magnet 21 may be moveable with respect to permanent magnets 23 in the Y-direction over a relatively long range and in the X-direction over a relatively short distance, while the permanent magnets 23 take care of bearing or supporting permanent magnet 21 in or substantially parallel to the Z-direction.

FIG. 4 depicts a support 25 that may be the support MT configured to support the patterning device MA, or the substrate table WT configured to support the substrate W (see FIG. 1) in the lithographic apparatus. The support 25 includes a bearing according to the invention. Substantially in between permanent magnets 23, configured in a linear shape, permanent magnets 21 provide a bearing for the support 25 in or substantially parallel to the Z-direction. In an embodiment, the bearing may have a stiffness in the Z-direction that is larger than 50 N/mm, or larger than 80 N/mm. In an embodiment, the bearing may have a negative stiffness in a direction substantially perpendicular to the Z-direction. The support 25 may be moveable in the Y-direction over a relatively long range and in the X-direction over a relatively short range. The support 25 may also be used for supporting a reticle masking device. The reticle masking device may be constructed and arranged to determine a size of a radiation beam on the patterning device. The reticle masking device may include blades that are synchronously moveable with the patterning device MA.

FIG. 5 depicts the support of FIG. 4 according to an embodiment of the invention. The support 25 includes actuators and sensors which can be used in a lithographic apparatus in the X-Y plane on the right side and in the X-Z plane on the left side. The support 25 is moveable in the Y-direction on a bearing comprising permanent magnets 23 and moveable permanent magnets 21. The support is provided with at least one actuator for actuating the support 25 in at least one of the remaining/other degrees of freedom (i.e. the X-direction, Y-direction and/or rotation around the Z-direction (Rz)) by exerting a force between the moveable support 25 and the rest of the lithographic apparatus, e.g. in a direction perpendicular to the Z-direction. The actuator is a Lorentz-force motor comprising a magnet 27 provided to the support 25 and a coil 29 connected to the rest of the apparatus for movements in the Y-direction. Another actuator being a Lorentz motor comprises a magnet 26 and coils 28 for movements in the X-direction.

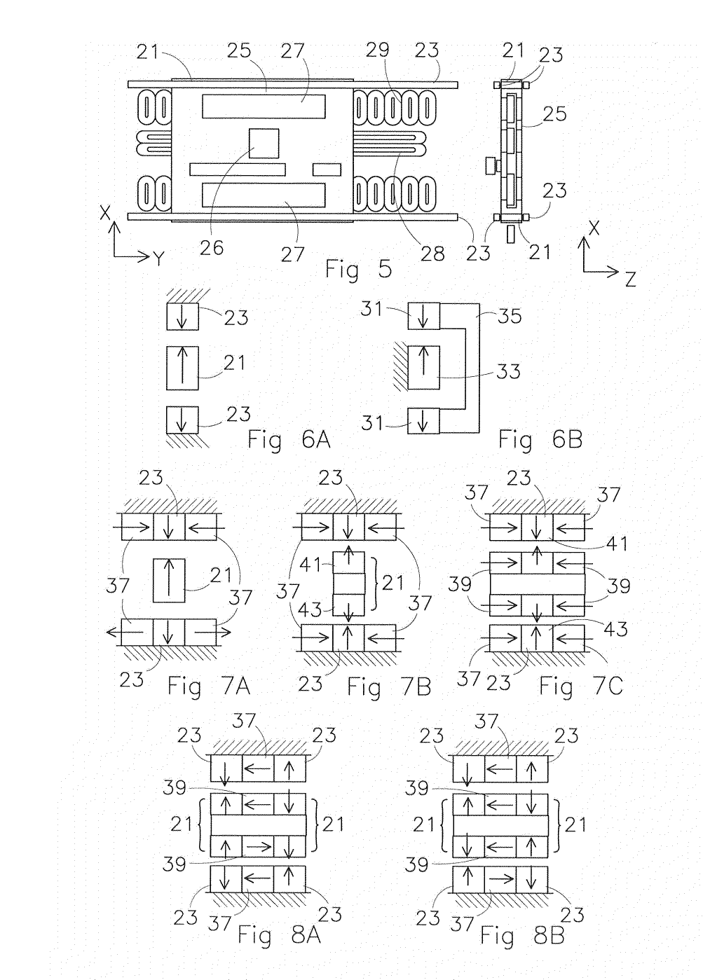

FIGS. 6A and 6B depict configurations of permanent magnets according to further embodiments of the invention. In FIG. 6A, permanent magnet 21 is provided for bearing substantially in the Z-direction between permanent magnets 23. The field orientation of the permanent magnets, indicated with an arrow is substantially parallel to the Z-direction. In FIG. 6B, an alternative is disclosed wherein permanent magnets 31 are connected to a moveable part via a mounting frame 35. The magnets provide bearing in substantially the Z-direction with respect to permanent magnet 33 which is mounted to a non moving part of the lithographic apparatus.

FIGS. 7A, 7B and 7C depict configurations of permanent magnets according to further embodiments of the invention. FIG. 7A depicts a bearing wherein permanent magnets 37 are positioned in a so-called Halbach array so as to improve the strength of the magnet field between the permanent magnets 23 connected to the not moveable part and the magnet 21 connected to the moveable part of the lithographic projection apparatus. The field orientation of the permanent magnets 37 indicated by an arrow in the Halbach configuration is perpendicular the Z-direction. The field orientation of the permanent magnets 21, 23 indicated with an arrow is substantially parallel to the Z-direction. FIG. 7B depicts a bearing wherein the moveable magnet 21 is divided in two permanent magnets 41, 43 with substantially opposite polarity and the polarity of the lower part of the non moveable part of the bearing has a substantially opposite polarity with respect to FIG. 7A. The magnets provided to the non-moveable part of the bearing are also provided with Halbach magnets 37. In FIG. 7C the moveable magnets 41, 43 are also provided with Halbach magnets 39 to enhance the magnetic field in between the moveable part of the bearing and the non-moveable part of the bearing.

FIG. 8 depicts configurations of permanent magnets according to further embodiments of the invention. Similar as in FIG. 7C, the moveable part of the bearing and the non moveable part of the bearing are provided with Halbach magnets. The non-moveable part is provided with two Halbach magnets 37 and the moveable part with two Halbach magnets 39. The non-moveable part is further provided with four permanent magnets 23 and the moveable part with four permanent magnets 21 the field orientation of the permanent magnets 21, 23, indicated with an arrow is substantially parallel to the Z-direction.

The bearing according to the invention may be used as a bearing for a masking device for masking a radiation beam. United States Patent Application Publication No. 2006/0139615, incorporated herein by reference discloses such a masking device. The masking device includes a guiding mechanism to guide a movable structure such as a mask blade, a movable part connected to the movable structure, and a substantially stationary part to guide the movable part. The movable part includes a motor drive part and a counter weight part connected to an end of the motor drive part facing away from the movable structure.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

What is claimed is:

1. A lithographic apparatus comprising:
an illumination system configured to provide a radiation beam;
a support configured to support a patterning device, the patterning device being configured to impart the radiation beam with a pattern in its cross-section to form a patterned radiation beam;
a substrate table configured to hold a substrate;
a projection system configured to project the patterned radiation beam onto a target portion of the substrate; and
a bearing configured to support a first part of the lithographic apparatus with respect to a second part of the lithographic apparatus in a first direction such that the first part is moveable in a second direction relative to the second part, the second direction being substantially perpendicular to the first direction,
wherein the first part is coupled to at least one permanent magnet, and the second part is coupled to at least two permanent magnets, the permanent magnet of the first part being positioned substantially between the permanent magnets of the second part,
wherein a field orientation of the permanent magnets is substantially parallel to the first direction,
wherein the permanent magnet of the first part has a substantially opposite polarity to at least one of the magnets of the second part, and
wherein the bearing is configured to restrict rotational movement of the first part around the second direction, and to restrict rotational movement of the first part around a third direction, the third direction being substantially perpendicular to the first direction and to the second direction.

2. The lithographic apparatus according to claim 1, wherein the lithographic apparatus further comprises an actuator configured to actuate the first part in at least one other degree of freedom by exerting a force between the first part and the second part.

3. The lithographic apparatus according to claim 2, wherein the lithographic apparatus further comprises a control system coupled to the actuator, wherein the control system is configured to control actuation of the first part in the at least one other degree of freedom.

4. The lithographic apparatus according to claim 1, wherein the first part is a masking device configured to mask a part of the radiation beam.

5. The lithographic apparatus according to claim 2, wherein the first part is a masking device configured to mask a part of the radiation beam.

6. The lithographic apparatus according to claim 3, wherein the first part is a masking device configured to mask a part of the radiation beam.

7. A device manufacturing method comprising:
providing a substrate that is at least partially covered by a layer of radiation-sensitive material on a substrate table;
providing a patterning device on a support;
projecting a patterned beam of radiation onto the layer of radiation sensitive material;
supporting with a bearing a first part of the lithographic apparatus with respect to a second part of the lithographic apparatus in a first direction such that the first part is moveable in a second direction relative to the second part, the second direction being substantially perpendicular to the first direction, the first part being coupled to at least one permanent magnet, the second part being coupled to at least two permanent magnets, the permanent magnet of the first part being positioned substantially between the permanent magnets of the second part, wherein a field orientation of the permanent magnets is substantially parallel to the first direction, and wherein the at least one permanent magnet of the first part has a substantially opposite polarity to at least one of the magnets of the second part;
restricting rotational movement of the first part around the second direction;
restricting rotational movement of the first part around a third direction, the third direction being substantially perpendicular to the first direction and to the second direction;
moving the first part with respect to the second part;
developing the layer of radiation-sensitive material on the substrate; and
manufacturing a device from the developed substrate.

8. The method according to claim 7, further comprising:
actuating the first part in at least one other degree of freedom by exerting a force between the first part and the second part.

9. The method according to claim 8, further comprising:
controlling the actuation of the first part in the at least one other degree of freedom.

10. The method according to claim 7, wherein the first part is a masking device and wherein the method further comprises masking a part of the radiation beam by the masking device.

11. The method according to claim 8, wherein the first part is a masking device and wherein the method further comprises masking a part of the radiation beam by the masking device.

12. The method according to claim 9, wherein the first part is a masking device and wherein the method further comprises masking a part of the radiation beam by the masking device.
